(19) United States
(12) Patent Application Publication
(10) Pub. No.: US 2015/0270159 A1
(43) Pub. Date: Sep. 24, 2015

(54) FABRICATION OF SEMICONDUCTOR STRUCTURES USING OXIDIZED POLYCRYSTALLINE SILICON AS CONFORMAL STOP LAYERS

(71) Applicant: GLOBALFOUNDRIES INC., Grand Cayman (KY)

(72) Inventors: Haigou HUANG, Rexford, NY (US); Hongliang SHEN, Ballston Lake, NY (US); Huang LIU, Mechanicville, NY (US); Tao HAN, Clifton Park, NY (US); Xiang HU, Clifton Park, NY (US)

(73) Assignee: GLOBALFOUNDRIES INC., Grand Cayman (KY)

(21) Appl. No.: 14/220,260

(22) Filed: Mar. 20, 2014

(51) Int. Cl. H01L 21/762; H01L 21/324; H01L 21/311; H01L 21/3105; H01L 21/02

(52) U.S. Cl. CPC H01L 21/76229; H01L 21/31056; H01L 21/02123; H01L 21/31105; H01L 21/02263; H01L 21/324; H01L 21/02337

(57) ABSTRACT

Semiconductor structure fabrication methods are provided which include: forming one or more trenches and a plurality of plateaus within a substrate structure; providing a conformal stop layer over the substrate structure, including over the plurality of plateaus, the conformal stop layer being or including oxidized polycrystalline silicon; depositing a material over the substrate structure to fill the one or more trenches and cover the plurality of plateaus thereof; and planarizing the material using a slurry to form coplanar surfaces of the material and the conformal stop layer, wherein the slurry reacts with the oxidized polycrystalline silicon of the conformal stop layer to facilitate providing the coplanar surfaces with minimal dishing of the material. Various embodiments are provided, including different methods of providing the conformal stop layer, such as by oxidizing at least an upper portion of polycrystalline silicon, or by performing an in-situ steam growth process.

### FIELD OF THE INVENTION

The present invention relates to methods of manufacturing semiconductor structures, and more particularly, to methods for fabricating semiconductor structures using conformal stop layers with oxidized polycrystalline silicon.

### BACKGROUND OF THE INVENTION

Semiconductor structures, such as integrated circuits, are typically fabricated in large batches from a semiconductor wafer. The semiconductor wafer is then diced into individual dies, or microchips, which are subsequently packaged. During integrated circuit fabrication, individual devices, such as transistors, may be isolated from one another by forming trenches between the devices and filling the trenches with an isolation material. Height variations of the isolation material across the wafer may occur, either within the wafer, or within the dies, leading to defects and loss of yield.

### BRIEF SUMMARY

The shortcomings of the prior art are overcome, and additional advantages are provided, through the provision, in one aspect, of a method for fabricating a semiconductor structure. The method includes: forming one or more trenches and a plurality of plateaus within a substrate structure; providing a conformal stop layer over the substrate structure, including over the plurality of plateaus, the conformal stop layer being or including oxidized polycrystalline silicon; depositing a material over the substrate structure to fill the one or more trenches and cover the plurality of plateaus thereof; and planarizing the material using a slurry to form coplanar surfaces of the material and the conformal stop layer, wherein the slurry reacts with the oxidized polycrystalline silicon of the conformal stop layer to facilitate providing the coplanar surfaces with minimal dishing of the material.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A is a cross-sectional elevational view of a structure obtained during one embodiment of a semiconductor structure fabrication process, in accordance with one or more aspects of the present invention;

FIG. 1B illustrates the structure of FIG. 1A, after forming one or more trenches and a plurality of plateaus within the substrate structure depicted, in accordance with one or more aspects of the present invention;

FIG. 1C illustrates the structure of FIG. 1B, after extending the trench into the substrate, in accordance with one or more aspects of the present invention;

FIG. 1D illustrates the structure of FIG. 1C, after removing an upper layer of the substrate structure, in accordance with one or more aspects of the present invention;

FIG. 1E illustrates the structure of FIG. 1D, after providing a conformal stop layer over the substrate structure, including within the trench(es) and over the plurality of plateaus, in accordance with one or more aspects of the present invention;

FIG. 1F illustrates the structure of FIG. 1E, after depositing a material over the substrate structure to fill the trench and cover the plurality of plateaus thereof, in accordance with one or more aspects of the present invention;

FIG. 1G illustrates the structure of FIG. 1F, after planarizing the material to form coplanar surfaces of the material and the conformal stop layer, in accordance with one or more aspects of the present invention;

FIG. 1H illustrates the structure of FIG. 1G, after performing a deglaze process to remove exposed portions of the conformal stop layer and recess material within the trench, in accordance with one or more aspects of the present invention;

FIG. 1I illustrates the structure of FIG. 1H, after removing one or more upper layers of the substrate structure, in accordance with one or more aspects of the present invention;

FIG. 2A is a cross-sectional elevational view of another embodiment of a structure obtained during a semiconductor structure fabrication process, in accordance with one or more aspects of the present invention;

FIG. 2B illustrates the structure of FIG. 2A, after removing an upper layer from the substrate structure, in accordance with one or more aspects of the present invention;

FIG. 2C illustrates the structure of FIG. 2B, after providing a conformal stop layer over the substrate structure, including over the plurality of plateaus, in accordance with one or more aspects of the present invention;

FIG. 2D illustrates the structure of FIG. 2C, after depositing a material over the substrate structure to fill the one or more trenches and cover the plurality of plateaus thereof, in accordance with one or more aspects of the present invention;

FIG. 2E illustrates the structure of FIG. 2D, after planarizing the material to form coplanar surfaces of the material and the conformal stop layer, in accordance with one or more aspects of the present invention; and

FIG. 2F illustrates the structure of FIG. 2E, after etching the material and the conformal stop layer to reveal a portion of the plurality of plateaus, in accordance with one or more aspects of the present invention.

### DETAILED DESCRIPTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and not by way of limitation. Various substitutions, modifications, additions, and/or arrangements, within the spirit and/or scope of the underlying inventive concepts will be apparent to those skilled in the art from this disclosure.

The present disclosure provides, in part, methods for fabricating semiconductor structures using conformal stop layers with oxidized polycrystalline silicon. During the fabrication of semiconductor devices, trenches and plateaus may be formed within a semiconductor structure. The plateaus may be used to form semiconductor devices, such as transistors, having active regions including source regions, drain regions, and channel regions. Between plateaus, the trenches may be filled with an isolation material, in order to provide (for instance) shallow trench isolation (STI) regions between the plateaus, laterally isolating the plateaus and the devices formed therein from one another.

Because other overlying structures, such as gate structures, may be formed above the STI regions, it is advantageous that the height of the isolation material be uniform across the many trenches. If the isolation material does not have a uniform height, within a die (WID) and within a wafer (WIW) step height variations may lead to downstream fabrication defects, which may cause yield loss. For example, step height variations could lead to material residues or missing gate structures, because downstream processes may be intolerant of height variations.

Chemical mechanical polishing (CMP) may be used to planarize the isolation material. In chemical mechanical polishing, a rotating polishing pad, in conjunction with an abrasive chemical slurry, is used to planarize a semiconductor wafer. A stop layer is a layer of material having a greater resistance to the planarizing than the isolation material. If a stop layer is provided over the plateaus of the substrate, the greater resistance of the stop layer may slow down the planarizing after the planarizing has formed coplanar surfaces of the isolation material and the stop layer. Depending on the devices being fabricated, the density of patterns of the plateaus of the substrate will vary across the die and the wafer.

The techniques disclosed herein may be used to reduce so-called dishing of material. Dishing may happen when excessive polishing removes excess material, to form a concave, or dish shaped, cavity in the material. This may occur because a stop layer does not maintain coplanar surfaces during the polishing. Dishing may be caused by, for example, enhanced sensitivity of the planarizing process to time variations. Disadvantageously, dishing leads to variations in the height of the material, such as an isolation material, across a chip or wafer. Because of the small dimensions and tolerances typically involved in semiconductor manufacturing, such height variations, and the presence of concavities, may lead to open circuits or short circuits of fabricated semiconductor devices, leading to reduced yield and greater overall fabrication costs.

In one example, dishing is caused because, during the planarizing, particles of the slurry accumulate over the material in a greater concentration than over the conformal stop layer, and the greater accumulation of slurry particles over the material causes erosion of the material. This may occur if, for example, a silicon nitride conformal stop layer is used in conjunction with a slurry including particles of, for example, cerium oxide, such as Ce₂O₃ or CeO₂, because the silicon nitride may repel the cerium oxide, causing the accumulation of slurry particles over the material. By contrast, in one embodiment of the present invention, the oxidized polycrystalline silicon does not repel the particles of a selected slurry, thus preventing uneven accumulations of slurry particles during the planarizing, and inhibiting potential dishing. For instance, in one specific example, the oxidized polycrystalline silicon chemically reacts with a slurry, such as a cerium oxide slurry, instead of repelling particles of the slurry. In such an example, the reacted portion of the conformal stop layer has a greater resistance to the planarizing than the material.

In another example, the techniques disclosed herein reduce the likelihood of dishing because the greater resistance of the conformal stop layer (to the planarizing) allows for coplanar surfaces of the material and the conformal stop layer to be maintained during the planarizing. For example, the properties of oxidized polycrystalline silicon, including, for instance, surface oxidized polycrystalline silicon, formed using the techniques disclosed herein, may increase the strength of the conformal stop layer, leading to less loss of the conformal stop layer during planarization, thus preventing dishing, and promoting die uniformity.

Generally stated, provided herein, in one aspect, is a method for fabricating a semiconductor structure. The method includes: forming one or more trenches and a plurality of plateaus within a substrate structure; providing a conformal stop layer over the substrate structure, including over the plurality of plateaus, the conformal stop layer being or including oxidized polycrystalline silicon; depositing a material over the substrate structure to fill the one or more trenches and cover the plurality of plateaus thereof; and planarizing the material using a slurry to form coplanar surfaces of the material and the conformal stop layer, wherein the slurry reacts with the oxidized polycrystalline silicon of the conformal stop layer to facilitate providing the coplanar surfaces with minimal dishing of the material. In one example, the planarizing includes using a slurry that includes cerium oxide, and the cerium oxide chemically reacts with the oxidized polycrystalline silicon of the conformal stop layer to form a reacted portion of the conformal stop layer.

In one example, the planarizing may include removing portions of the material and the conformal stop layer concurrently to form the coplanar surfaces of the material and the conformal stop layer. In another example, the planarizing could include chemical mechanical polishing the material. In a further example, the planarizing may include anisotropically etching the material.

In one embodiment, the providing may include: conformally providing polycrystalline silicon over the substrate structure, including within the one or more trenches and over the plurality of plateaus; and oxidizing at least an upper portion of the polycrystalline silicon. In such a case, the oxidizing may include annealing the polycrystalline silicon. In another embodiment, the oxidizing may include oxidizing an exposed surface of the polycrystalline silicon. In a further embodiment, the providing may include performing an in-situ steam growth process to conformally form oxidized polycrystalline silicon.

In one implementation, the method may further include stopping the planarizing within a predetermined time period after forming the coplanar surfaces, where the conformal stop layer slows the planarizing to prevent complete removal of the conformal stop layer during the predetermined time period. In such a case, the predetermined time period may be between about 10 to 20 seconds, and the planarizing may remove no more than about 6 to 8 angstroms of the material and the conformal stop layer within the predetermined time period.

In another implementation, the method may further include etching the material and the conformal stop layer to reveal a portion of the plurality of plateaus. In a further implementation, the method may further include removing exposed portions of the conformal stop layer. In such a case, the removing may include performing a deglaze process to remove the exposed portions of the conformal stop layer.

In one example, the material is a dielectric material which may electrically isolate laterally one plateau of the plurality of plateaus from another plateau of the plurality of plateaus. In another example, the substrate structure may include one or more layers disposed over a substrate, and the one or more trenches may extend through the one or more layers to the substrate. In a further example, a first trench of the one more trenches could have a first width, and a second trench of the one or more trenches could have a second width, the first width being different from the second width, and a first upper surface of the material in the first trench may be coplanar with a second upper surface of the material in the second trench.

In one specific implementation, the depositing of the material may include chemical vapor deposition of the material to fill the one or more trenches. In another specific implementation, the depositing of the material may include performing a high aspect ratio deposition process to fill the one or more trenches. In a further specific implementation, the conformal stop layer may have a thickness of between 30 and 40 angstroms.

Reference is made below to the drawings, which are not drawn to scale for ease of understanding, wherein the same reference numbers used throughout different figures designate the same or similar components.

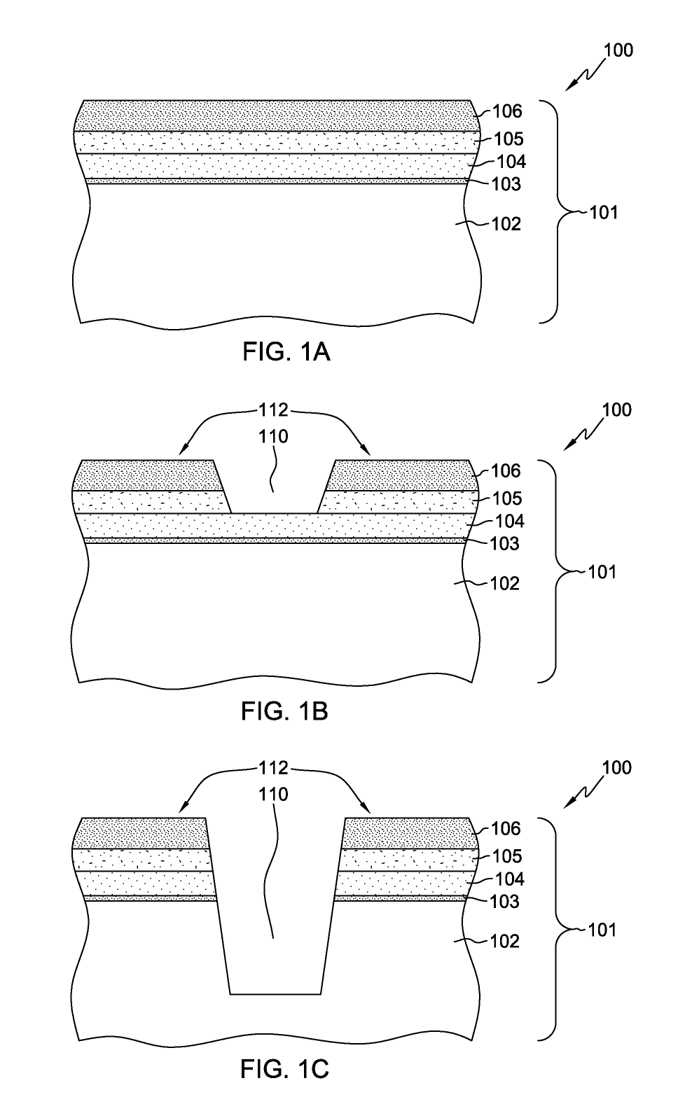

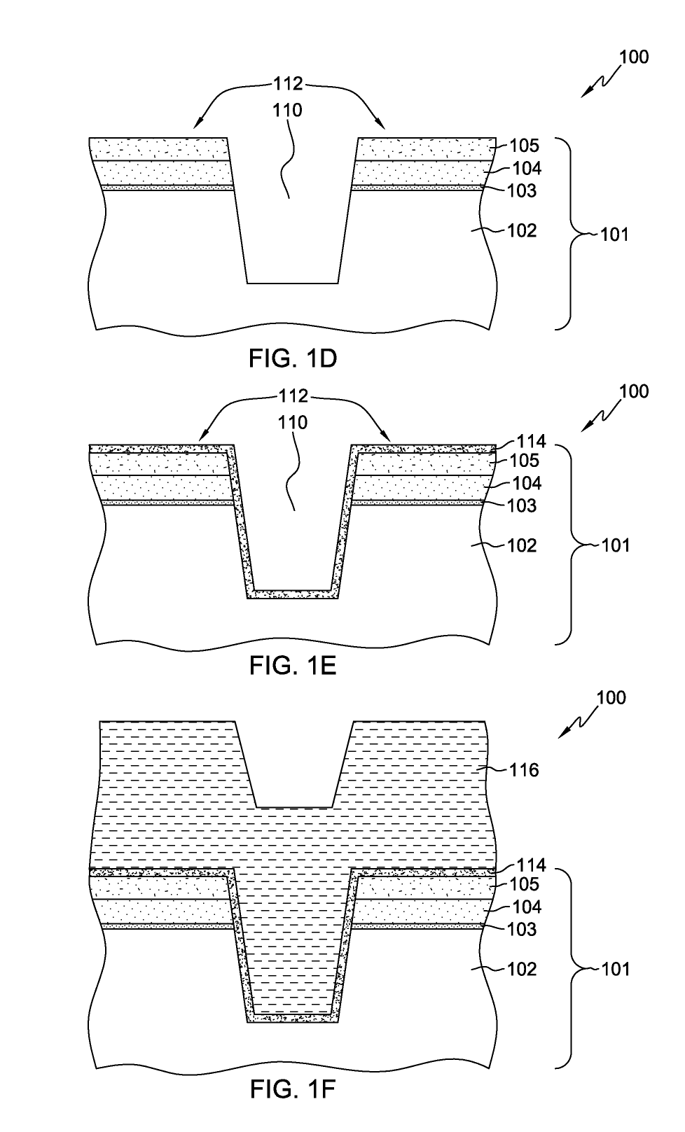

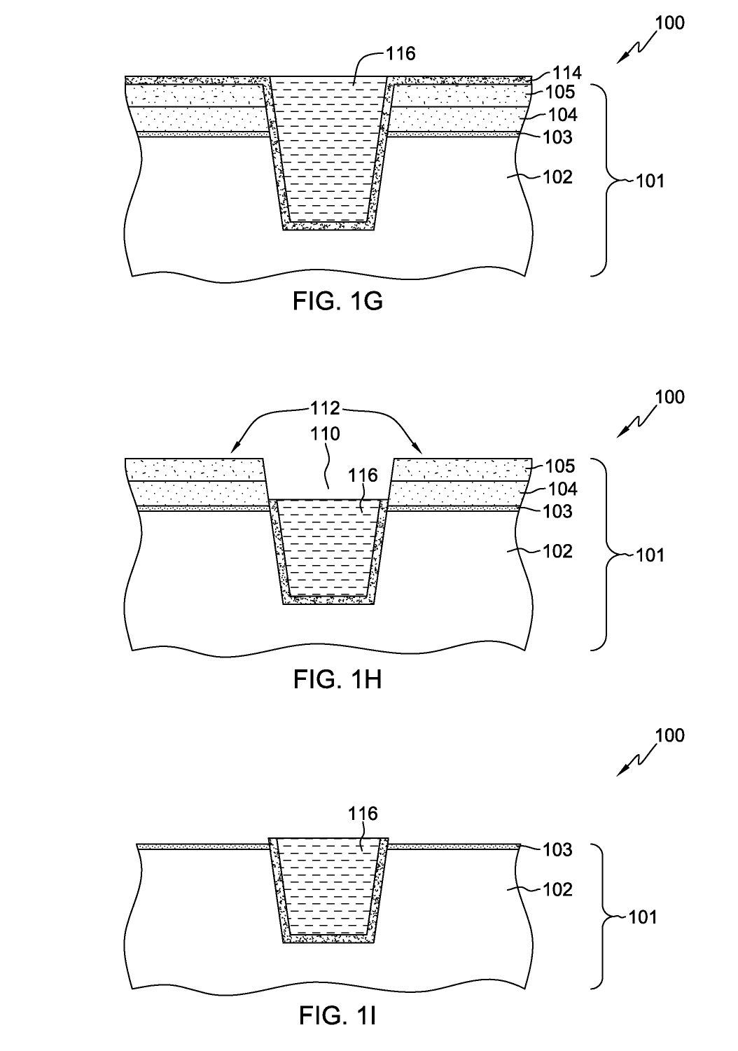

FIG. 1A is a cross-sectional elevation view of one embodiment of a structure 100 obtained during an intermediate stage of semiconductor structure fabrication processing, in accordance with one or more aspects of the present invention. In one example, structure 100 may be or include a wafer, from which numerous microchips may be fabricated. Semiconductor structure fabrication includes forming numerous semiconductor devices on structure 100, and the techniques described herein may be repeated multiple times during the fabrication.

Structure 100 may include a substrate structure 101, which may include one or more layers disposed over a substrate 102. In one specific example, the one or more layers may facilitate patterning and etching to form one or more trenches within substrate structure 101, and may be used, for example, as a double layer hard mask. For example, layer 103 may be an oxide layer, layer 104 may be a nitride layer, layer 105 may be a polycrystalline silicon layer, and layer 106 may be another oxide layer, such as an un-doped silicon oxide (UDOx). In one specific example, layer 103 may have a thickness of 3.5 nm, layer 104 may have a thickness of 25 nm, layer 105 may have a thickness of 20 nm, and layer 106 may have a thickness of 20 nm, as one example only. These layers may be formed using a variety of different materials and fabrication techniques, such as chemical vapor deposition (CVD), atomic layer deposition (ALD), physical vapor deposition (PVD) or plasma-enhanced versions of such processes. The thickness of the depicted layers may also vary, depending on the particular application.

Substrate 102 may be (in one example) a bulk semiconductor material such as a bulk silicon wafer. In another example, substrate 102 may be or include any silicon-containing substrate material including, but not limited to, single crystal Si, polycrystalline Si, amorphous Si, Si-on-nothing (SON), Si-on-insulator (SOI), or Si-on-replacement insulator (SRI) substrates and the like, and may be n-type or p-type doped as desired for a particular application. In one example, substrate 102 may be, for instance, a wafer or substrate approximately 600-700 micrometers thick, or less. The semiconductor substrate may include other suitable elementary semiconductors, such as, for example, germanium (Ge) in crystal, or a compound semiconductor such as silicon carbide (SiC), gallium arsenide (GaAs), gallium phosphide (GaP), indium phosphide (InP), indium arsenide (InAs), and/or indium antimonide (InSb) or combinations thereof or an alloy semiconductor including GaAsP, AlInAs, GaInAs, GaInP, or GaInAsP or combinations thereof.

FIGS. 1B-1C illustrate the structure of FIG. 1A after forming one or more trenches 110 and a plurality of plateaus 112 within substrate structure 101. At the stage of fabrication depicted in FIG. 1B, trench 110 may extend through layer 106 and layer 105 to layer 104 (in one example). Trench 110 may be formed by any of a variety of trench formation processes, which may include one or more steps of patterning and removal of material.

In one example of a trench formation process, substrate structure 101 may be patterned using various approaches, including direct lithography, sidewall image transfer techniques, extreme ultraviolet lithography (EUV), e-beam techniques, litho-etch litho-etch technique, or litho-etch litho-freeze technique. Following patterning, material of substrate structure 101 may be removed to form trench 110 and the plurality of plateaus 112. Removal may be accomplished using any suitable removal process, such as an etching process with an etchant selective to, for instance, the materials of layer 105 and layer 106, but not layer 104, so that the etching stops at layer 104, as depicted. In one example, etching may be an anisotropic etching, such as reactive ion etching (RIE), using an appropriate chemistry, depending on the material of the layers being etched. In a specific example, the reactive ion etching may be performed using fluorine based chemistry and gases such as tetrafluoromethane (CE), trifluoromethane (CHF₃), difluoromethane (CH₂F₂), fluoromethane (CH₃F), octofluoromethane (C₄F₈), hexafluoro-1,3-butadiene (C₄F₆), sulfur hexafluoride (SF₆), oxygen (O₂), and the like.

Referring to FIG. 1C, in one embodiment, trench 110 may be extended through the one or more layers to or into substrate 102, using another trench formation process. Multiple different trench formation processes may be employed to optimize removal of one or more of the depicted layers having different compositions. For example, trench 110 may be extended by etching with an etchant selective to layer 103 and layer 104, but not layer 106, so that trench 110 is deepened, but not widened.

FIG. 1D illustrates the structure of FIG. 1C after removing layer 106 of substrate structure 101. Layer 106 may be removed using any suitable etching or cleaning process, selective to the material of layer 106. In one example, layer 106 may have served the purpose of protecting underlying layers and/or structures in other regions of structure 100 during the trench formation processes described herein.

FIG. 1E illustrates the structure of FIG. 1D after providing a conformal stop layer 114 over substrate structure 101. As depicted, conformal stop layer 114 is provided over plateaus 112 and within trench(es) 110. As used herein, a conformal layer is a layer of material which to the contours of the structure upon which it is provided.

In one implementation, conformal stop layer 114 may include, for example, oxidized polycrystalline silicon. In one specific example, conformal stop layer 114 may have a thickness of between 30 Å to 40 Å. Conformal stop layer 114 may have a uniform thickness, or the thickness may vary in different regions of substrate structure 101.

A variety of processes may be used to provide conformal stop layer 114. One example process may include conformally providing polycrystalline silicon over substrate structure 101, including within trench(es) 110 and over plateaus 112, and oxidizing at least an upper portion of the polycrystalline silicon to provide the oxidized polycrystalline silicon. In one specific example, oxidizing the polycrystalline silicon may be achieved by annealing the structure. For example, structure 100 may be annealed at between 900° C. and 1000° C., for between 5 and 25 minutes, in the presence of water vapor.

The oxidizing may be performed concurrently with, before, or after, conformally providing the polycrystalline silicon. In another example, the oxidizing could include oxidizing only a portion of the polycrystalline silicon, such as an upper portion or an exposed surface.

In a further example, an in-situ steam growth (ISSG) process could be performed to conformally form oxidized polycrystalline silicon, and thereby provide conformal stop layer 114. In such a process, polycrystalline silicon may be deposited concurrently with a steam process in the presence of oxygen to form the oxidized polycrystalline silicon. In one embodiment of an ISSG process performed on a wafer, the process is performed at a low pressure (such as 11 Torr), in a cold wall rapid thermal processing reactor chamber. In such an embodiment, H₂ and O₂ gases are introduced directly into the chamber without pre-combustion, and the hot wafer acts as an ignition source. In one example, the oxidation temperature may be between 900° C. and 1050° C. and a ratio of H₂:O₂ may be between 0% and 25%.

FIG. 1F illustrates the structure of FIG. 1E after depositing a material 116 over substrate structure 101 to fill trench(es) 110 and cover plateaus 112. Material 116 may be an isolation material or dielectric material, and may be deposited using a variety of techniques, such as, for example, chemical vapor deposition (CVD), plasma-enhanced CVD, or sub-atmospheric pressure thermal CVD (SACVD) processes. The thickness of material 116 may be (in one example) sufficient to allow for subsequent planarization of the structure. By way of example, material 116 may be fabricated of or include an oxide material. For instance, high-density plasma (HDP) oxide, high aspect ratio process (HARP)-oxide or tetraethyl orthosilicate (TEOS)-based silicon dioxide may be deposited as material 116, using plasma-enhanced CVD process. In a specific example, the chemical vapor deposition process may be employed using tetraethyl orthosilicate (TEOS) and ozone (O₃) as reactants to deposit the tetraethyl orthosilicate based silicon dioxide to fill trench(es) 110 and cover plateaus 112.

FIG. 1G illustrates the structure of FIG. 1F after planarizing material 116 to form coplanar upper surfaces of material 116 and conformal stop layer 114. In order to facilitate achieving such coplanar surfaces, conformal stop layer 114 may be selected to have a greater resistance to the planarizing process than material 116.

In one embodiment, the planarizing may be stopped within a predetermined time period after forming the coplanar surfaces. The conformal stop layer slows the planarizing once the coplanar surfaces are achieved, and during the predetermined time period, portions of material 116 and conformal stop layer 114 will be removed concurrently, maintaining the coplanar surfaces. Such an embodiment may eliminate variability in the heights of the surfaces, facilitating achieving the desired coplanar surfaces, even with variations in the predetermined time period or variations in an initial thickness of conformal stop layer 114.

In one specific example, the predetermined time period may be between 10 and 20 seconds, and the planarizing, having slowed down at conformal stop layer 114, may only remove between 6 Å and 8 Å within the predetermined time period. In such a case, if conformal stop layer has a thickness of between 30 Å and 40 Å, the coplanar surfaces would be maintained, despite variation in the predetermined time period.

Regarding the planarizing process, in one example, planarizing may include chemical mechanical polishing (CMP) material 116, using a slurry, such as, for example, a cerium oxide slurry. In the CMP process, a polishing pad, in conjunction with the slurry, may be used to planarize material 116. In another example, the planarizing may also include anisotropically etching material 116. As explained above, if, during the planarizing, particles of the slurry accumulate over the material, and are depleted over the conformal stop layer, the accumulated slurry particles may cause erosion of the material, leading to dish-shaped concavities. In one embodiment of the present invention, oxidized polycrystalline silicon advantageously does not repel and chemically reacts with particles of a slurry used in the planarizing process. In such an embodiment, the chemical reaction advantageously prevents repulsion of particles, and facilitates even planarizing of the material and the conformal stop layer. In one specific example, cerium oxide is not repelled by oxidized polycrystalline silicon, and the materials chemically react to form a reacted portion of the conformal stop layer. In such an example, the reacted portion of the conformal stop layer may have a greater resistance to the planarizing than a resistance to the planarizing of material 116.

FIGS. 1H & 1I illustrate further processing that may be performed after material 116 has been planarized to have the same height across the wafer or die. Such processing includes recessing material 116 using, for example, etching processes that facilitate the removal of small amounts of material predictably to maintain the height of the material across the wafer or dies. Therefore, in the processing steps illustrated in FIGS. 1H & 1I, conformal stop layer 114 is removed, and material 116 is recessed a relatively small amount, while maintaining the consistency of height across the wafer or die.

FIG. 1H illustrates the structure of FIG. 1G, after performing a deglaze process to remove exposed portions of conformal stop layer 114. In one example, a dry deglaze process may be employed, using reactive ion etching in a pressure chamber, with a pressure of between 1 and 250 mTorr, to selectively remove the portions of conformal stop layer 114, and a predictable thickness of material 116. In another example, depending on the chemical composition of material 116, the deglaze process may be used in the presence of different selected gases to enhance the selectivity of the process. For example, the deglaze process may employ any appropriate gas, such as CF₄, CHF₃, CH₂F₂, C₄F₆, C₅F₈, C₄F₈, Ar, He, O₂, N₂, or the like.

FIG. 1I illustrates the structure of FIG. 1H, after removing layers of substrate structure 101. The layers may be removed using any suitable etching process. For example, a polycrystalline silicon layer could be removed using TMAH, and a silicon nitride layer could be removed using a hot phosphorous process. Subsequent to the removal the selected layers, material 116 may have a uniform height within different regions of structure 100, including within the same die, and within the wafer. The uniform height may then facilitate subsequent processing steps of structure 100 to manufacture multiple chips and devices with a reduced number of defects due to height variation.

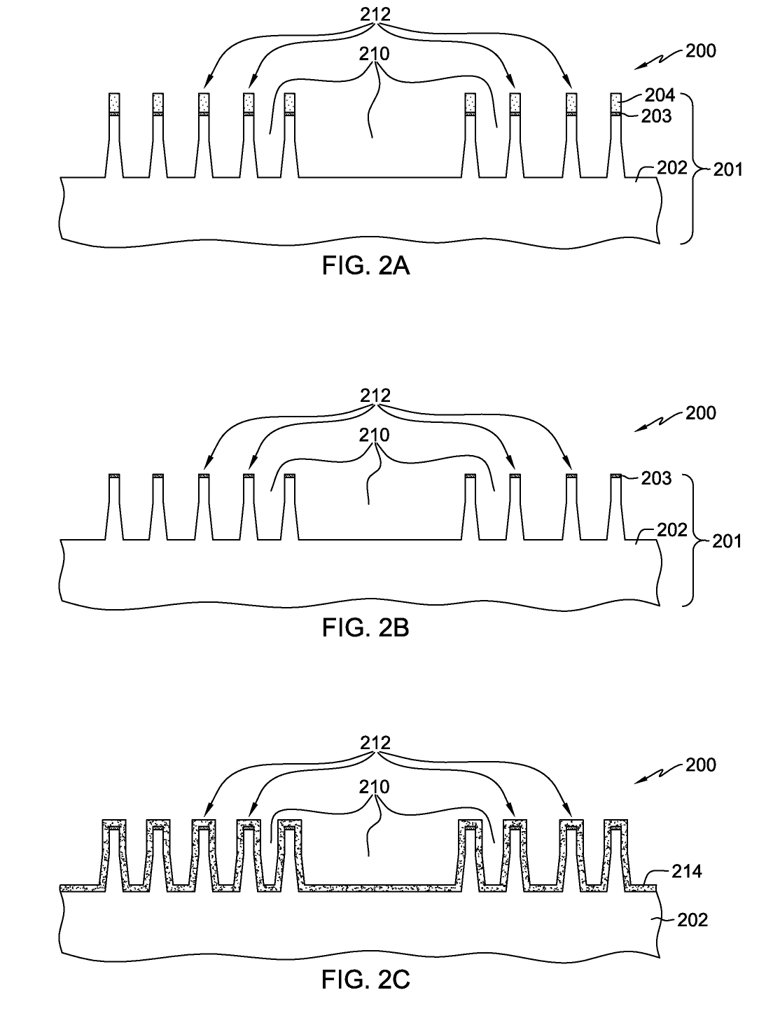

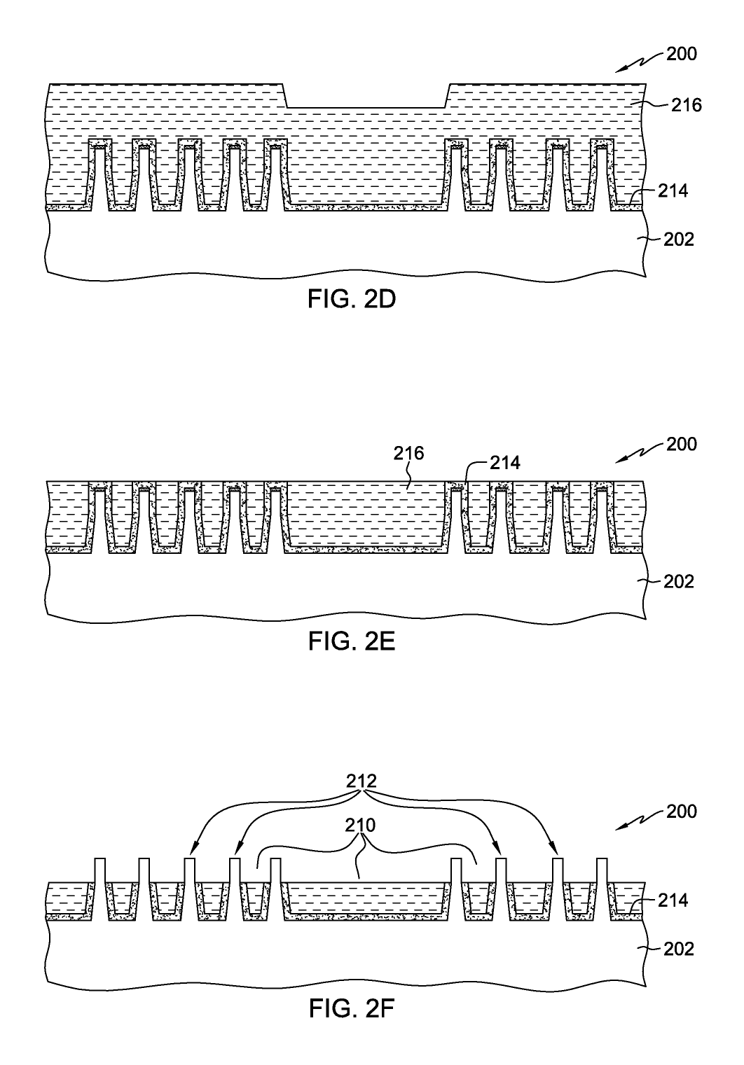

FIGS. 2A-2F illustrate another embodiment of a method for fabricating semiconductor structures using conformal stop layers with oxidized polycrystalline silicon, in accordance with one or more aspects of the present invention. Any of the various processing methods and techniques described above with respect to FIGS. 1A-1I may also be applicable to the process of FIG. 2A-2F depending on the structure being fabricated.

FIG. 2A is a cross-sectional elevation view of a structure 200 obtained during semiconductor structure fabrication, having trenches 210 and a plurality of plateaus 212. As illustrated, in one embodiment, plateaus 212 may be fin structures, which may include active regions of field effect transistors formed or to be formed within structure 200. For example, the fin structures may include a three-dimensional channel region between a source region and a drain region.

FIG. 2B illustrates the structure of FIG. 2A, after removing layer 204. In one example, layer 204 may have been a mask used in the formation of plateaus 212. For example, layer 204 may have been deposited over a substrate structure 201, and patterned using, for example, photo-lithographic patterning techniques. Subsequently, trenches 210 may have been formed by using etching, such as anisotropic etching, selective to layer 204.

FIG. 2C illustrates the structure of FIG. 2B, after providing a conformal stop layer 214 over substrate structure 201. As depicted, conformal stop layer 214 is provided over plateaus 212 and within trenches 210. As shown, one or more of trenches 210 may have different widths. The spacing of plateaus 212 and trenches 210 may be quite different within different portions of a die, or within different dies on a wafer, depending on the architecture and design of the circuits to be formed. Conformal stop layer 214 may be or include oxidized polycrystalline silicon. In other examples, structure 200 may be directly oxidized to form oxidized silicon. In such a case, a portion of substrate structure 201, including plateaus 212 may be consumed by the oxidizing. Such a process may change the critical dimensions of structure 200. By contrast, by depositing conformal stop layer 214, no critical dimensions are changed, and no portions of substrate structure 201 (including trenches 212) are consumed.

FIG. 2D illustrates the structure of FIG. 2C after, depositing a material 216 over substrate structure 101 to fill the one or more trenches and cover the plurality of plateaus. Given the potentially high aspect ratio of trenches 210 (the ratio of the height to the width), a high aspect ratio process (HARP) may be required to ensure that material 216 flows into trenches 210. Any of the techniques previously described with respect to FIG. 1F may be applied to deposit material 216.

FIG. 2E illustrates the structure of FIG. 2D after, planarizing material 216 to form coplanar surfaces of material 216 and conformal stop layer 214. As illustrated, a first trench of the one or more trenches, for example, located in the center of FIG. 2E, may have a first width, and a second trench of the one or more trenches, for example, located either to the right or left of the first trench in FIG. 2E, may have a second width. In the example portrayed, the first width is different (larger) from the second width. In other embodiments, the first width may be between 2 and 10,000 times larger, or the first width may extend to nearly the width of the wafer, depending on the specific configuration employed.

During the planarization process described herein, conformal stop layer 214 ensures that a first upper surface of material 216 in the first trench is coplanar with a second upper surface of material 216, despite the difference in width of the first and second trenches. Conformal stop layer 214 therefore prevents the previously described dishing phenomenon, in which concavities may be formed in material 216 due to limitations of a planarization technique.

FIG. 2F illustrates the structure of FIG. 2E, after etching material 216 and conformal stop layer 214 to reveal of portion of the plurality of plateaus 212. In one example, the exposed portions of plateaus 212 may be or include active regions of semiconductor devices to be formed from the plateaus. For example, if plateaus 212 are fin structures, then the exposed portions of the fin structures may be used, in part, as three-dimensional channel regions for semiconductor devices formed thereon, and material 216 may electrically isolate, laterally, one fin structure from another fin structure. Lateral electrical isolation may prevent, for example, leakage current from traveling from one fin structure to another fin structure, due to, for instance, insulator properties of material 216.

In one example, trenches 212 may be revealed through a post planarizing cleaning process. For instance, sulfuric peroxide mix (SPM) also known as Piranha solution or piranha etch, may be employed. SPM may be a mixture of sulfuric acid (H₂SO₄) and hydrogen peroxide (H₂O₂), used to clean organic residues off substrates. Because SPM is a strong oxidizer, it will remove most organic matter, and it will also hydroxylate most surfaces (add OH groups), making them extremely hydrophilic (water compatible).

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method comprising:
fabricating a semiconductor structure, the fabricating comprising:
forming one or more trenches and a plurality of plateaus within a substrate structure;
providing a conformal stop layer over the substrate structure, including over the plurality of plateaus, the conformal stop layer comprising oxidized polycrystalline silicon;
depositing a material over the substrate structure to fill the one or more trenches and cover the plurality of plateaus; and
planarizing the material using a slurry to form coplanar surfaces of the material and the conformal stop layer, wherein the slurry reacts with the oxidized polycrystalline silicon of the conformal stop layer to facilitate providing the coplanar surfaces with minimal dishing of the material.

2. The method of claim 1, wherein the providing comprises:
conformally providing polycrystalline silicon over the substrate structure, including within the one or more trenches and over the plurality of plateaus; and
oxidizing at least an upper portion of the polycrystalline silicon.

3. The method of claim 2, wherein the oxidizing comprises annealing the polycrystalline silicon.

4. The method of claim 2, wherein the oxidizing comprises oxidizing an exposed surface of the polycrystalline silicon.

5. The method of claim 1, wherein the providing comprises performing an in-situ steam growth process to conformally form the oxidized polycrystalline silicon.

6. The method of claim 1, wherein the planarizing comprises removing portions of the material and the conformal stop layer concurrently to form the coplanar surfaces of the material and the conformal stop layer.

7. The method of claim 1, wherein the planarizing comprises chemical mechanical polishing the material.

8. The method of claim 1, wherein the slurry comprises cerium oxide, and the cerium oxide chemically reacts with the oxidized polycrystalline silicon of the conformal stop layer to form a reacted portion of the conformal stop layer.

9. The method of claim 1, wherein the planarizing comprises anisotropically etching the material.

10. The method of claim 1, further comprising stopping the planarizing within a predetermined time period after forming the coplanar surfaces, wherein the conformal stop layer slows the planarizing to prevent complete removal of the conformal stop layer during the predetermined time period.

11. The method of claim 10, wherein the predetermined time period is between about 10 to 20 seconds, and the planarizing removes no more than about 6 to 8 angstroms of the material and the conformal stop layer within the predetermined time period.

12. The method of claim 1, further comprising etching the material and the conformal stop layer to reveal a portion of the plurality of plateaus.

13. The method of claim 1, further comprising removing exposed portions of the conformal stop layer.

14. The method of claim 13, wherein the removing comprises performing a deglaze process to remove the exposed portions of the conformal stop layer.

15. The method of claim 1, wherein the conformal stop layer has a thickness of between 30 and 40 angstroms.

16. The method of claim 1, wherein the depositing of the material comprises chemical vapor deposition of the material to fill the one or more trenches.

17. The method of claim 1, wherein the depositing of the material comprises performing a high aspect ratio deposition process to fill the one or more trenches.

18. The method of claim 1, wherein the material is a dielectric material which electrically isolates laterally one plateau of the plurality of plateaus from another plateau of the plurality of plateaus.

19. The method of claim 1, wherein the substrate structure comprises one or more layers disposed over a substrate, and the one or more trenches extend through the one or more layers to the substrate.

20. The method of claim 1, wherein a first trench of the one more trenches has a first width, and a second trench of the one or more trenches has a second width, the first width being different from the second width, and a first upper surface of the material in the first trench is coplanar with a second upper surface of the material in the second trench.
